(19) United States
(12) Patent Application Publication
(10) Pub. No.: US 2026/0033029 A1
(43) Pub. Date: Jan. 29, 2026

(54) SURFACE PASSIVATION FOR DEEP TRENCH ISOLATION STRUCTURE

(71) Applicant: Taiwan Semiconductor Manufacturing Company, Ltd., Hsinchu (TW)

(72) Inventors: U-Ting Chiu, Hsinchu (TW); Bing Cheng You, Taichung City (TW); Hsin-Hung Chen, Tainan City (TW); Wen-I Hsu, Tainan City (TW); Ming-En Chen, Tainan City (TW); Feng-Chi Hung, Chu-Bei City (TW); Jen-Cheng Liu, Hsin-Chu City (TW); Dun-Nian Yaung, Taipei City (TW)

(21) Appl. No.: 18/780,591

(22) Filed: Jul. 23, 2024

(51) Int. Cl. H01L 27/146

(52) U.S. Cl. CPC H10F 39/807; H10F 39/024

(57) ABSTRACT

Some embodiments relate to a pixel array, including: a substrate; a plurality of photodetectors within the substrate; a deep trench isolation (DTI) structure with segments extending between photodetectors of the plurality of photodetectors, the DTI structure comprising: a first oxide layer having a first oxygen density; a first metal oxide layer lining inner sidewalls of the first oxide layer and having a second oxygen density greater than the first oxygen density; a second oxide layer lining inner sidewalls of the first metal oxide layer and having a third oxygen density less than the second oxygen density; and a second metal oxide layer lining inner sidewalls of the second oxide layer and having a fourth oxygen density greater than the third oxygen density.

### BACKGROUND

Integrated circuits (ICs) with image sensors are used in a wide range of modern-day electronic devices, such as, for example, cameras, cellphones, and the like. Image sensors use a plurality of photodetectors to convert incoming light into electrical signals. A signal processing circuit converts the electrical signals into a computer readable image. To prevent cross-talk or interference between photodetectors of the plurality of photodetectors, deep trench isolation (DTI) structures extend between the photodetectors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a cross-sectional view and a top view of some embodiments of a DTI structure with complementary dipole generating layers.

FIGS. 2A and 2B illustrate cross-sectional views of some embodiments of a photodetector array with the DTI structure of FIGS. 1A and 1B.

FIGS. 3A and 3B illustrate graphs of defect densities and flat band voltages of different embodiments of the DTI structure with complementary dipole generating layers.

FIG. 4 illustrates a cross-sectional view of some embodiments of a DTI structure with complementary dipole generating layers including a third dipole generating layer.

FIGS. 5-14 illustrate a series of cross-sectional views of some embodiments of a method of forming a DTI structure with complementary dipole generating layers.

FIG. 15 illustrates a flowchart of some embodiments of a method of forming a DTI structure with complementary dipole generating layers.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

An image sensor comprises a pixel array with a plurality of photodetectors and a plurality of pixel circuits coupled to the photodetectors. The plurality of pixel circuits comprise a floating diffusion region, a transfer transistor extending between the floating diffusion region and the photodetector, and an interconnect structure coupling the floating diffusion region to an output stage. The plurality of photodetectors is organized in a plurality of rows and a plurality of columns, and the plurality of rows and the plurality of columns are delineated by a deep trench isolation (DTI) structure. The DTI structure surrounds the photodetectors of the plurality of photodetectors, isolating them from one another to reduce noise and interference.

As photodetector technology continues to progress, arrays with smaller photodetectors are desired to increase the resolution of the resulting image and reduce the size of the photodetector array. DTI structures are formed by etching trenches into a substrate and depositing one or more insulative layers within the trenches. The etching of the trenches results in damage such as dangling bonds forming in the substrate at the edges of the trenches. One way of reducing the size of the photodetectors is to reduce the width of the trenches formed, increasing the critical dimension (e.g., a ratio of the depth and the width) of the etch. Increasing the critical dimension, however, results in greater damage being done to the surrounding substrate. The damaged sidewalls of the substrate result in an increased dark current and reduced white pixel performance within the photodetectors, reducing their performance. Some methods of reducing this damage or surface passivation include utilizing more advanced tools in the etching process and more expensive materials. These methods are costly, however. Therefore, a method of inexpensively increasing the surface passivation of the DTI structure without utilizing expensive materials is desirable.

The present disclosure provides for a DTI structure with complementary dipole generating layers. The layering of metal oxide layers and oxide layers with differing oxygen densities result in dipoles near the surface of the DTI structure. The dipoles introduce an electric field at the interface between the DTI structure and the substrate. When the metal oxide layers have a greater oxygen density than the oxide layers, and a oxide layer is between the metal oxide layers and the substrate, the resulting electric field forms a depletion region in the sidewalls of the substrate surrounding the DTI structure. The depletion region comprises a plurality of holes at the sidewalls of the substrate. Electrons emitted from dangling bonds and damaged portions of the sidewalls of the substrate combine with the plurality of holes, capturing the carriers of the dark current before they may enter the photodetector or floating diffusion region. This reduction in the dark current and improved white pixel performance enhances the performance of the resulting photodetector array.

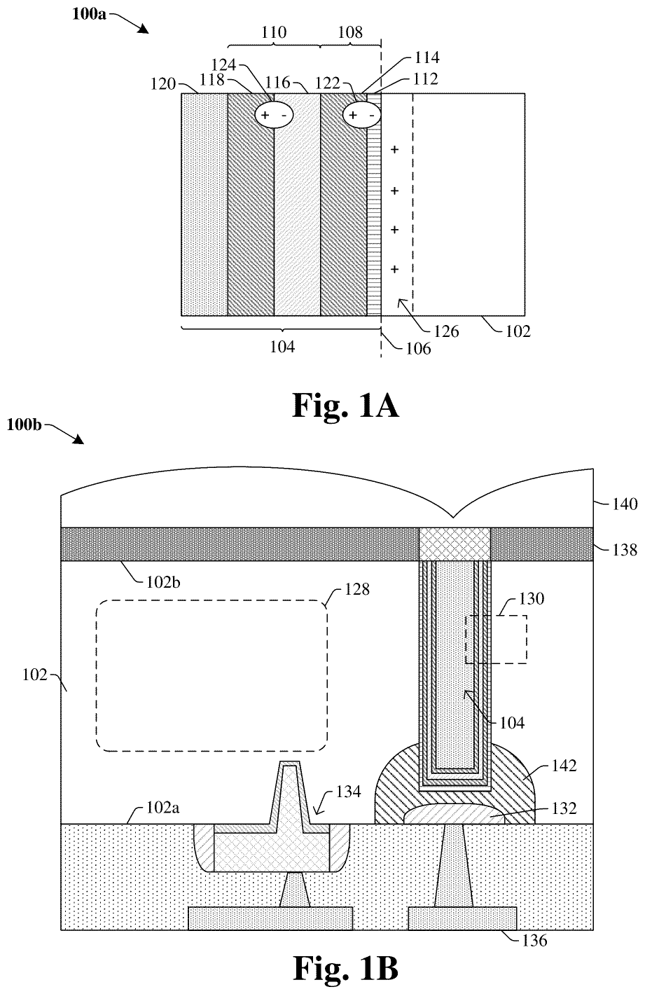

FIGS. 1A and 1B illustrate cross-sectional views 100a, 100b of some embodiments of a DTI structure with complementary dipole generating layers.

As shown in FIG. 1A, a DTI structure 104 contacts a substrate 102 at a first interface 106. The DTI structure 104 comprises a first dipole generating layer 108 and a second dipole generating layer 110. The first dipole generating layer 108 has a first oxide layer 112 and a first metal oxide layer 114. The second dipole generating layer 110 has a second oxide layer 116 and a second metal oxide layer 118. In some embodiments, a DTI fill 120 lines sidewalls of the second dipole generating layer 110.

The first oxide layer 112 has a first oxygen density and the first metal oxide layer 114 has a second oxygen density that is greater than the first oxygen density. In some embodiments, the first oxygen density is less than 1.25 grams per cubic centimeter, and/or ranges between 1.4 grams per cubic centimeter and 0.25 grams per cubic centimeter. In some embodiments, the second oxygen density is greater than 1.35 grams per cubic centimeter, and/or ranges between 1.3 grams per cubic centimeter and 3 grams per cubic centimeter. The difference in oxygen densities between the first oxide layer 112 and the first metal oxide layer 114 results in a first dipole 122 within the first dipole generating layer 108. The second oxide layer 116 has a third oxygen density and the second metal oxide layer 118 has a fourth oxygen density that is greater than the third oxygen density. The difference in oxygen densities between the second oxide layer 116 and the second metal oxide layer 118 results in a second dipole 124 within the first dipole generating layer 108. In some embodiments, the first oxygen density and the third oxygen density are approximately equal (e.g., within 10% of one another). In some embodiments, the second oxygen density and the fourth oxygen density are approximately equal (e.g., within 10% of one another). In other embodiments, the second oxygen density and the fourth oxygen density are different from one another.

The first dipole 122 enhances an electric field at the first interface 106, increasing the width of a depletion region 126 within the substrate 102 lining the first interface 106. The depletion region 126 has a greater number of positive charge carriers (e.g., holes) than negative charge carriers (e.g., electrons). The difference in the concentration of charge carriers results in electrons from the dangling bonds and damage at the interface to be more likely to recombine with a positive charge carrier before exiting the depletion region 126. The proximity of the second dipole generating layer 110 to the first dipole generating layer 108 results in the second dipole 124 further enhancing the electric field at the first interface 106, increasing a flat line voltage (e.g., a voltage applied to the DTI structure 104 that would result in no conduction band bending at the first interface 106). Increasing the flat line voltage results in a greater concentration of positive charge carriers being present in the depletion region, thereby reducing the dark current and increasing the white pixel performance of the photodetector array.

As shown in FIG. 1B, a first photodetector 128 is within the substrate 102. A portion 130 of the DTI structure 104 corresponding to FIG. 1A is shown in phantom. In some embodiments, the DTI structure overlies a floating diffusion region 132 on a first side 102a of the substrate 102. A transfer transistor 134 is between the first photodetector 128 and the floating diffusion region 132. An interconnect structure 136 is coupled to the floating diffusion region 132 and the transfer transistor 134. The interconnect structure 136 couples the floating diffusion region 132 to an output stage (not shown). The transfer transistor 134 is coupled to a charge transfer circuit that controls when the transfer transistor 134 transfers charge from the photodetector 128 to the floating diffusion region 132. An array of color filters 138 extend over the first photodetector 128. An array of microlenses 140 extend over the color filters 138.

In some embodiments, the floating diffusion region 132 is surrounded by a positive well 142. The positive well 142 separates the floating diffusion region 132 from the photodetector 128. During operation, applying a voltage greater than the voltage threshold of the transfer transistor 134 induces a channel through the positive well 142 between the first photodetector 128 and the floating diffusion region 132. In some embodiments, the transfer transistor 134 contacts the positive well 142 at a first side 102a of the substrate 102.

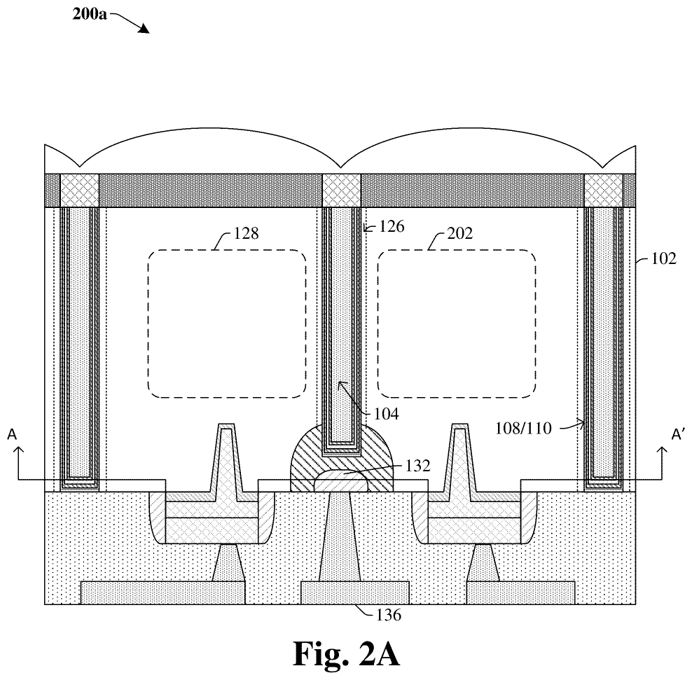

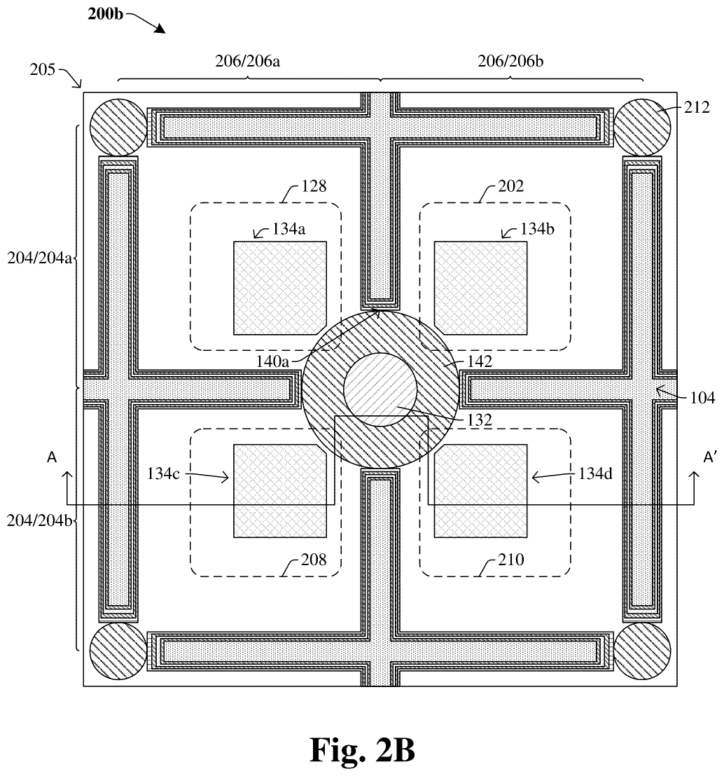

FIGS. 2A and 2B illustrate a cross-sectional view 200a and a top view 200b of some embodiments of a photodetector array with the DTI structure of FIGS. 1A and 1B. The cross-sectional view 200a of FIG. 2A is taken across line A-A′ of the top down view of FIG. 2B.

As shown in the cross-sectional view 200a of FIG. 2A, a second photodetector 202 is within the substrate 102 and is spaced from the first photodetector 128 by the DTI structure 104. The DTI structure 104 comprises a plurality of segments forming continuous rings surrounding the first photodetector 128 and the second photodetector 202. The first and second dipole generating layers 108, 110 extend across outer sidewalls and bottom surfaces of the DTI structure 104, resulting in all sides of the DTI structure 104 being isolated from the first and second photodetectors 128, 202 by the depletion region 126. In some embodiments, the first photodetector 128 and the second photodetector 202 share the floating diffusion region 132. That is, one floating diffusion region 132 couples the first photodetector 128 and the second photodetector 202 to the interconnect structure 136.

As shown in the top view 200b of FIG. 2B, a plurality of photodetectors 205 (including the first photodetector 128 and the second photodetector 202) are arranged into a plurality of rows 204 and a plurality of columns 206. The plurality of rows 204 and the plurality of columns 206 are separated by the plurality of segments of the DTI structure 104. A first row 204a of the plurality of rows 204 comprises the first photodetector 128 and the second photodetector 202. A second row 204b of the plurality of rows 204 comprises a third photodetector 208 and a fourth photodetector 210. A first column 206a of the plurality of columns 206 comprises the first photodetector 128 and the third photodetector 208. A second column 206b of the plurality of columns 206 comprises the second photodetector 202 and the fourth photodetector 210. In some embodiments, the floating diffusion region 132 is coupled to the first, second, third, and fourth photodetectors 128, 202, 208, 210 by a plurality of transfer transistors (e.g., first, second, third, and fourth transistors 134a, 134b, 134c, 134d, respectively).

In some embodiments, the positive well 142 extends to sidewalls 140a of the DTI structure 104 closest to the floating diffusion region 132. In other embodiments, the positive well 142 extends past the sidewalls 140a, covering the sidewalls 140a. The positive well 142 provides greater isolation between the plurality of photodetectors 205 in the region surrounding the floating diffusion region 132. In some embodiments, body contacts 212 are spaced from the floating diffusion region 132 by the plurality of photodetectors 205.

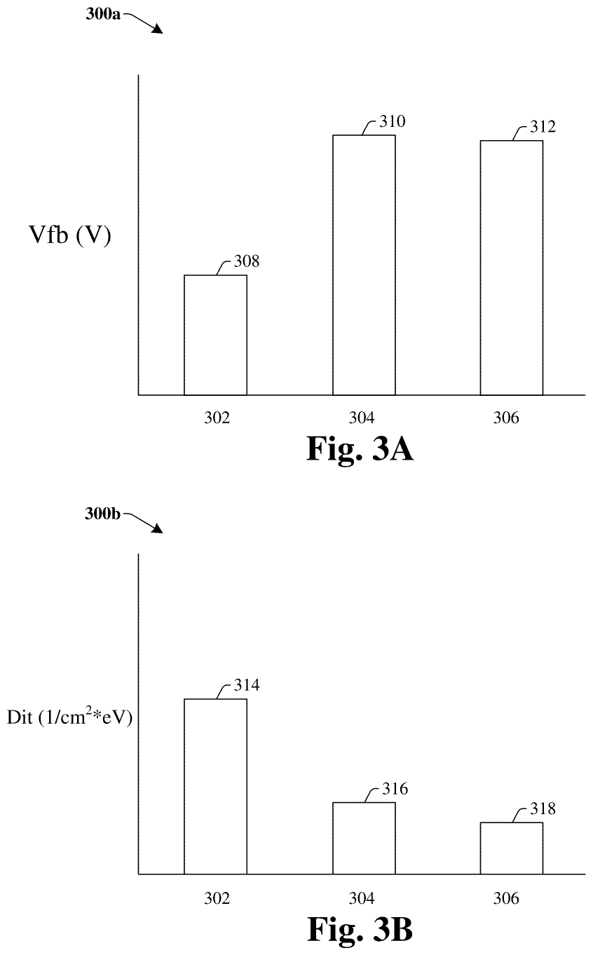

FIGS. 3A and 3B illustrate graphs 300a, 300b of flat band voltages and defect densities of different embodiments of the DTI structure with complementary dipole generating layers.

As shown in the graph 300a of FIG. 3A, a flat band voltage 308 of a first embodiment 302 with a single dipole generating layer (e.g., the second dipole generating layer 110 of FIG. 1A is omitted) are compared to flat band voltages 310, 312 of embodiments 304, 306 with complementary dipole generating layers of vary widths. Second embodiments 304 have complementary dipole generating layers (e.g., multiple dipole generating layers with aligned dipoles that reinforce the electric field at the first interface) as well as first and second metal oxide layers 114, 118 (see FIG. 1A) with thicknesses less than 50 angstroms. Third embodiments 306 have complementary dipole generating layers (e.g., multiple dipole generating layers with aligned dipoles that reinforce the electric field at the first interface) as well as first and second metal oxide layers 114, 118 (see FIG. 1A) with thicknesses greater than 50 angstroms.

In some embodiments, the flat band voltages 310, 312 of the embodiments 304, 306 with complementary dipole generating layers are over double the flat band voltage 308 of the first embodiment 302. The flat band voltages 308, 310, 312 correspond to the degree of upwards band bending of the fermi level in the substrate (see 102 of FIG. 1A) when the DTI structure (see 104 of FIG. 1A) is not externally biased. The increased flat band voltages 310, 312 of the embodiments 304, 306 with complementary dipole generating layers result in a greater degree of upwards band bending in the substrate (see 102 of FIG. 1A), which indicates a higher concentration of holes at the first interface (see 106 of FIG. 1A).

As shown in the graph 300b of FIG. 3B, a measured defect density 314 of the first embodiment 302 with a single dipole generating layer is greater than the measured interface trap densities 316, 318 of the second and third embodiments 304, 306. The interface trap densities are found by interpreting capacitance-voltage characteristics at the interface between the substrate (see 102 of FIG. 1A) and the DTI structure (see 104 of FIG. 1A). The enhanced passivation of the second and third embodiments 304, 306 with complementary dipole generating layers result in a reduced interface trap density compared to a first embodiments 302 with a single dipole generating layer. In some embodiments, second embodiments 304 with first and second metal oxide layers 114, 118 (see FIG. 1A) with thicknesses less than 50 angstroms have a greater interface trap density 316 than the interface trap density 318 of third embodiments 306 with first and second metal oxide layers 114, 118 (see FIG. 1A) with thicknesses greater than 50 angstroms.

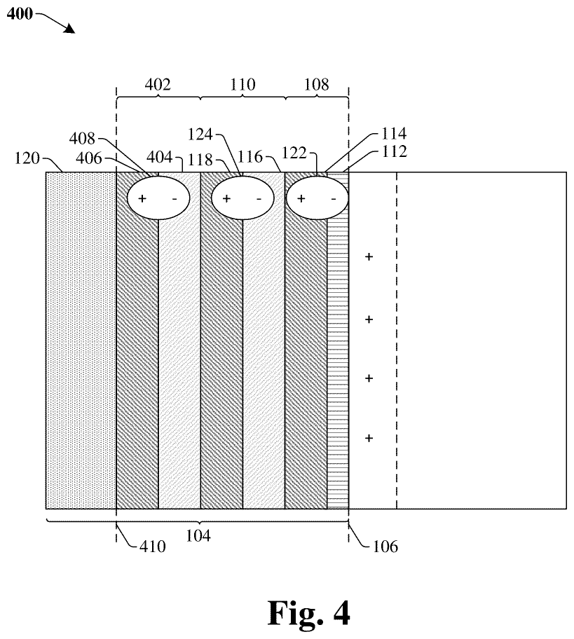

FIG. 4 illustrates a cross-sectional view 400 of some embodiments of a DTI structure with complementary dipole generating layers including a third dipole generating layer.

In some embodiments, a third dipole generating layer 402 separates the second dipole generating layer 110 from the DTI fill 120. The third dipole generating layer comprises a third oxide layer 404 and a third metal oxide layer 406 that form a third dipole 408. When the oxygen density of the third metal oxide layer 406 is greater than the oxygen density of the third oxide layer 404, the third dipole 408 has a same orientation (e.g., a positive charge oriented towards the DTI fill 120 and a negative charge oriented towards the first interface 106) as the second dipole 124 and the first dipole 122. In some embodiments, when the third dipole generating layer 402 is formed near (e.g., within a first distance 410 of the first interface 106), the third dipole generating layer 402 increases the flat band voltage and reduces the interface trap density at the first interface 106. In other embodiments, when the third dipole generating layer 402 is further than the first distance 410 from the first interface 106, the third dipole generating layer 402 has a reduced effect on the flat band voltage and the interface trap density at the first interface 106. In some embodiments, the first distance is between 200 and 300 angstroms, between 250 and 350 angstroms, between 225 and 325 angstroms, or the like. That is, a total thickness of the combination of dipole layers (e.g., the combined thickness of the first dipole generating layer 108, the second dipole generating layer 110, and in some embodiments, the third dipole generating layer 402) is less than 225 angstroms, less than 250 angstroms, less than 300 angstroms, or the like.

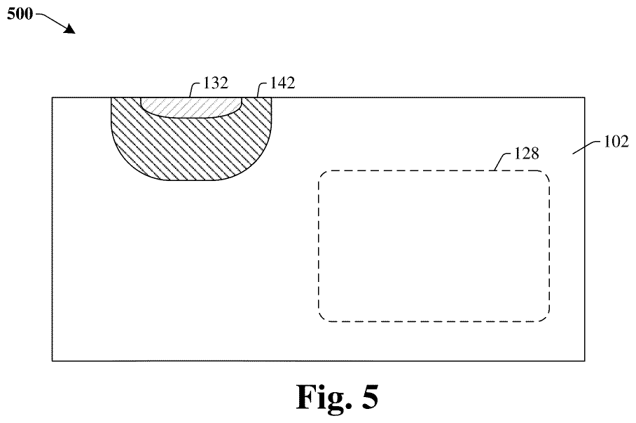

FIGS. 5-10, 11A, 11B, 11C, 11D, 12, 13A, 13B, and 14 illustrate a series of cross-sectional views 500-1000, 1100a, 1100b, 1100c, 1100d, 1200, 1300a, 1300b, 1400 of some embodiments of a method of forming a DTI structure with complementary dipole generating layers. Although FIGS. 5-10, 11A, 11B, 11C, 11D, 12, 13A, 13B, and 14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 500 of FIG. 5, the first photodetector 128, the floating diffusion region 132, and the positive well 142 are formed within the substrate 102. The first photodetector 128, the floating diffusion region 132, and the positive well 142 are formed using a plurality of ion implantation processes. For example, in some embodiments the first photodetector 128 is formed by applying and patterning a first mask (not shown), then performing a first ion implantation process to implant n-type dopants into the substrate 102 according to the first mask. In some embodiments the positive well 142 is formed by applying and patterning a second mask (not shown), then performing a second ion implantation process to implant p-type dopants into the substrate 102 according to the first mask. In some embodiments the floating diffusion region 132 is formed by applying and patterning a third mask (not shown), then performing a third ion implantation process to implant n-type dopants into the substrate 102 according to the first mask. In some embodiments, the plurality of photodetectors (see 205 of FIG. 2A) are formed concurrently with the first photodetector 128.

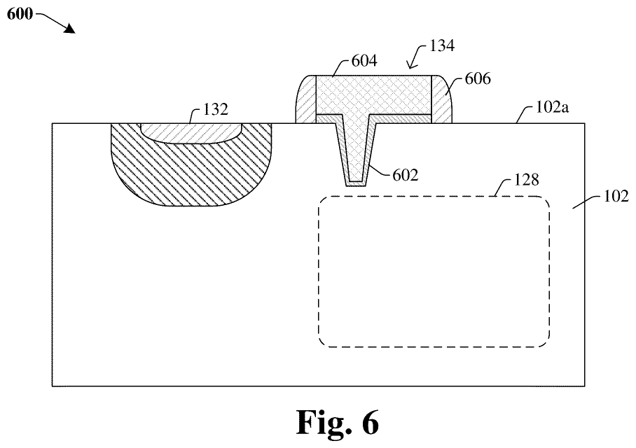

As shown in the cross-sectional view 600 of FIG. 6, the transfer transistor 134 is formed on a first side 102a of the substrate 102. The transfer transistor 134 extends between the first photodetector 128 and the floating diffusion region 132. In some embodiments, the transfer transistor 134 is formed by etching an opening in the substrate 102, forming a gate dielectric 602 on the first side 102a of the substrate 102 and within the opening, and forming a gate electrode 604 over the gate dielectric 602. In some embodiments, an insulative layer 606 is formed before or after the formation of the gate electrode 604. In some embodiments, forming the transfer transistor comprises one or more etching processes, one or more patterning processes, one or more deposition processes (e.g., processes such as physical vapor deposition (PVD), atomic layer deposition (ALD), chemical vapor deposition (CVD)), or the like. In some embodiments, the gate dielectric 602 is or comprises an insulative material such as silicon dioxide (SiO₂), silicon nitride (Si₃N₄), or the like. In some embodiments, the gate electrode 604 is or comprises a conductive material, such as copper, aluminum, tungsten, a conductive metal alloy, or the like.

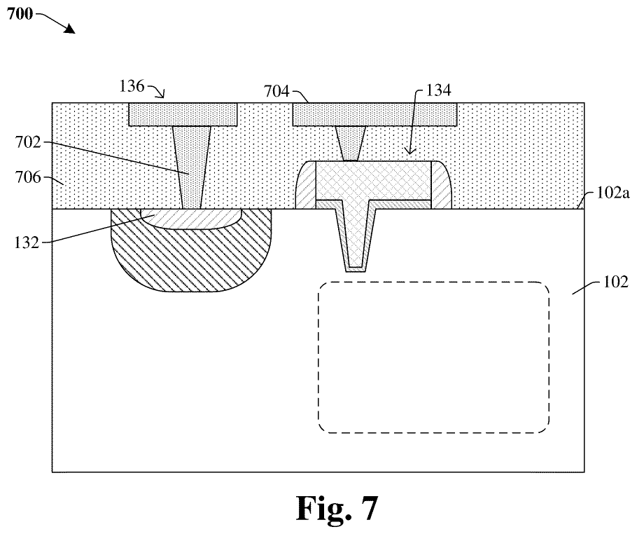

As shown in the cross-sectional view 700 of FIG. 7, the interconnect structure 136 is formed on the first side 102a of the substrate 102. The interconnect structure 136 comprises a plurality of contacts 702 coupled to the floating diffusion region 132 and the transfer transistor 134, and a plurality of wires 704 coupled to the plurality of contacts 702. In some embodiments, the plurality of wires 704 are part of one or more wire levels (not shown) coupled by one or more via levels (not shown). An interlayer dielectric 706 surrounds the interconnect structure 136. In some embodiments, the interconnect structure 136 is or comprises a conductive material, such as copper, aluminum, tungsten, a conductive metal alloy, or the like. In some embodiments, the interlayer dielectric 706 is or comprises an insulative material such as silicon dioxide (SiO₂), silicon nitride (Si₃N₄), or the like. In some embodiments, the interconnect structure 136 is formed using one or more etching processes to etch openings for the contacts and wires within the interlayer dielectric 706, as well as a deposition process, such as PVD, ALD, or CVD. In some embodiments, the interconnect structure 136 is formed using a damascene process, a dual damascene process, or the like.

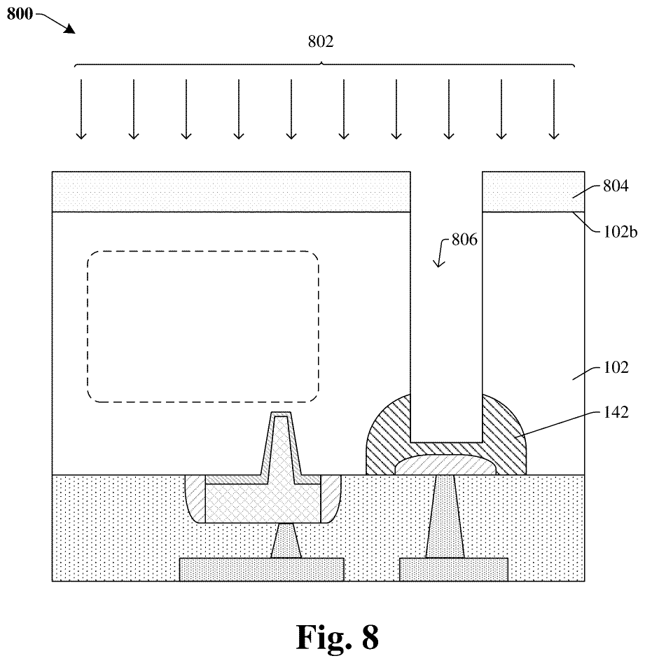

As shown in the cross-sectional view 800 of FIG. 8, a fourth masking layer 804 is formed over a second side 102b of the substrate 102. In some embodiments, the fourth masking layer 804 comprises a photoresist and is formed using a deposition process, a spin on process, a dipping process, or the like. The fourth masking layer 804 is then patterned, exposing portions of the second side 102b of the substrate 102 corresponding to the position of the DTI structure (see 104 of FIG. 1B) yet to be formed. In some embodiments, the fourth masking layer 804 is patterned using photolithography or the like.

After the fourth masking layer 804 has been patterned, a first etching process 802 is performed. The first etching process 802 forms a plurality of trenches 806 within the substrate 102. In some embodiments, the first etching process 802 forms trenches that extend into to the positive well 142. The first etching process 802 further results in damaged portions and dangling bonds being formed in the inner sidewalls of the substrate 102. In some embodiments, the first etching process comprises one or more dry etches to form a plurality of trenches with differing depths. In further embodiments, the one or more dry etches are separated by the removal and formation of additional masking layers.

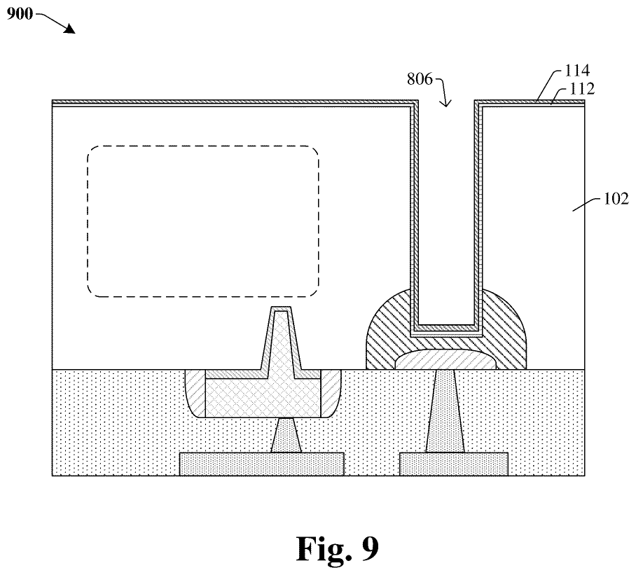

As shown in the cross-sectional view 900 of FIG. 9, the first metal oxide layer 114 is deposited over the substrate 102 and into the plurality of trenches 806. The deposition of the first metal oxide layer 114 results in the first oxide layer 112 being formed, as the substrate 102 at the inner sidewalls absorbs draws atoms from the first metal oxide layer 114 and makes a thin insulative layer of silicon dioxide (SiO₂). The first metal oxide layer 114 lines inner sidewalls of the first oxide layer 112. In some embodiments, the first metal oxide layer 114 is or comprises a metal oxide with a greater oxygen density than silicon dioxide (SiO₂), such as aluminum oxide (Al₂O₃), hafnium oxide (HfO₂), or the like. In some embodiments, the first metal oxide layer 114 is formed using one of PVD, ALD, or CVD.

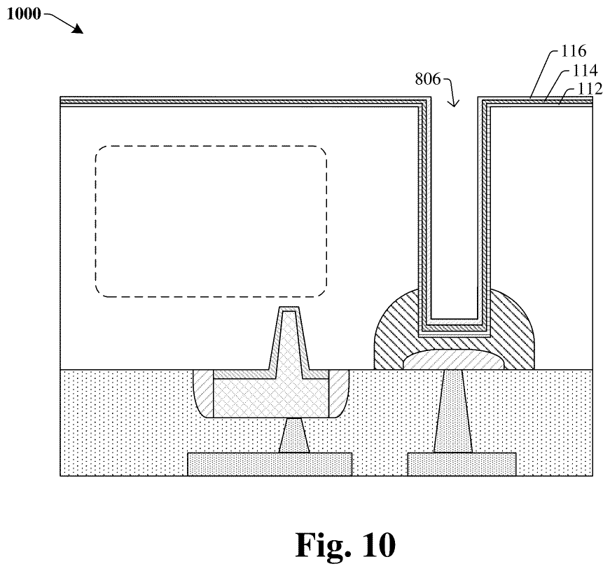

As shown in the cross-sectional view 1000 of FIG. 10, the second oxide layer 116 is deposited over the first metal oxide layer 114 and into the plurality of trenches 806. In some embodiments, the second oxide layer 116 is or comprises silicon dioxide (SiO₂) or another insulative oxide with an oxygen density less than the oxygen density of the first metal oxide layer 114. In some embodiments, the second oxide layer 116 has a greater thickness than the first oxide layer 112. In other embodiments, the second oxide layer 116 has a thickness that is approximately equal to (e.g., varying by about 10% from) the thickness of the first oxide layer 112. In some embodiments, the first metal oxide layer 114 is formed using one of PVD, ALD, or CVD.

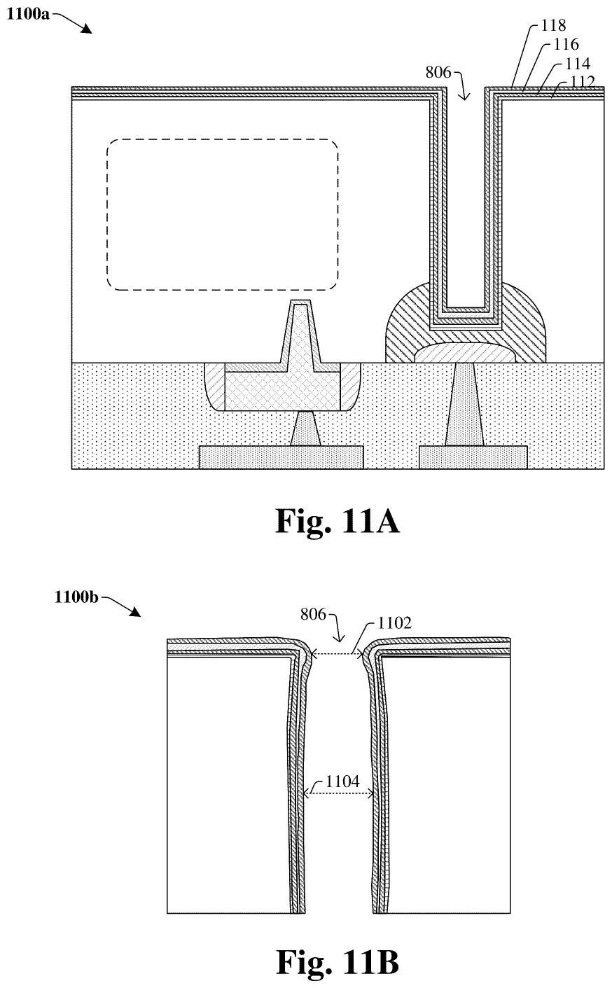

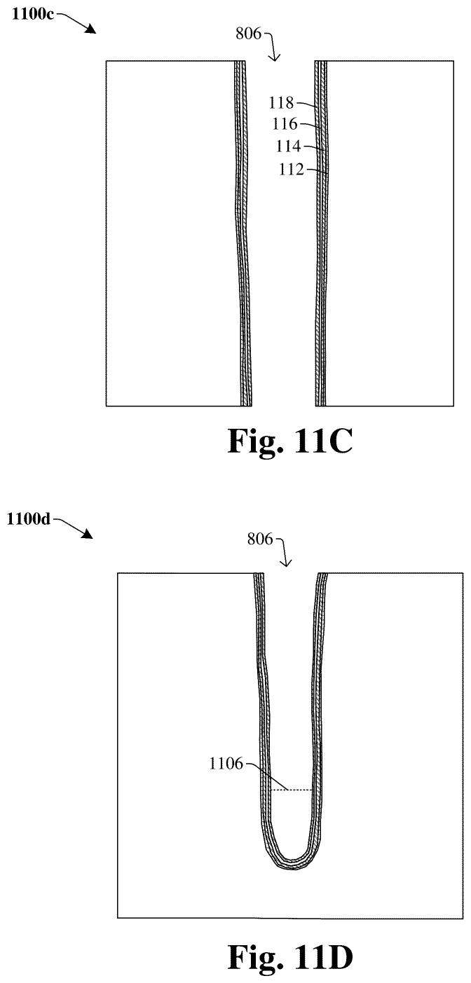

As shown in the cross-sectional view 1100a of FIG. 11A, the second metal oxide layer 118 is deposited over the substrate 102 and into the plurality of trenches 806. In some embodiments, the second metal oxide layer 118 is or comprises a metal oxide with a greater oxygen density than silicon dioxide (SiO₂), such as aluminum oxide (Al₂O₃), hafnium oxide (HfO₂), or the like. In some embodiments, the material of the second metal oxide layer 118 is the same as a material of the first metal oxide layer 114. In some embodiments, the first metal oxide layer 114 is formed using one of PVD, ALD, or CVD.

As shown in the cross-sectional view 1100b of FIG. 11B, in some embodiments, after forming the second metal oxide layer 118, the plurality of trenches 806 have a first width 1102 at an opening of the plurality of trenches (e.g., level with the second side 102b of the substrate 102). Further, the plurality of trenches 806 have a second width 1104 within the plurality of trenches 806 (e.g., beneath the second side 102b of the substrate 102), where the second width 1104 is less than the first width 1102.

As shown in the cross-sectional view 1100c of FIG. 11C, in some embodiments, the width of the plurality of trenches 806 is approximately equal (e.g., varies by less than 10%) across a central portion of the plurality of trenches 806. Further, the thicknesses of the first oxide layer 112, the first metal oxide layer 114, second oxide layer 116, and the second metal oxide layer 118 may vary within a first range (e.g., varies by less than 10% of the average thickness of the layer). As shown in the cross-sectional view 1100d of FIG. 11D, in some embodiments, the plurality of trenches 806 have a third width 1106 that is less than the first width and the second width (see 1104 of FIG. 11B) in a portion of the plurality of trenches 806 near the bottommost surface. That is, the plurality of trenches 806 taper as they reach the bottommost surface, gradually reducing in width.

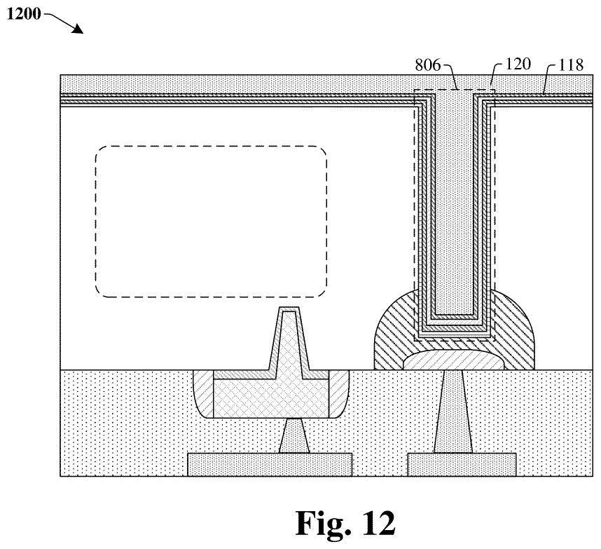

As shown in the cross-sectional view 1200 of FIG. 12, the DTI fill 120 is formed over the second metal oxide layer 118 within the plurality of trenches 806, filling them. In some embodiments, the DTI fill 120 is or comprises polysilicon, silicon dioxide, or an insulative material. In some embodiments, the DTI fill 120 is formed using one or more of PVD, ALD, or CVD.

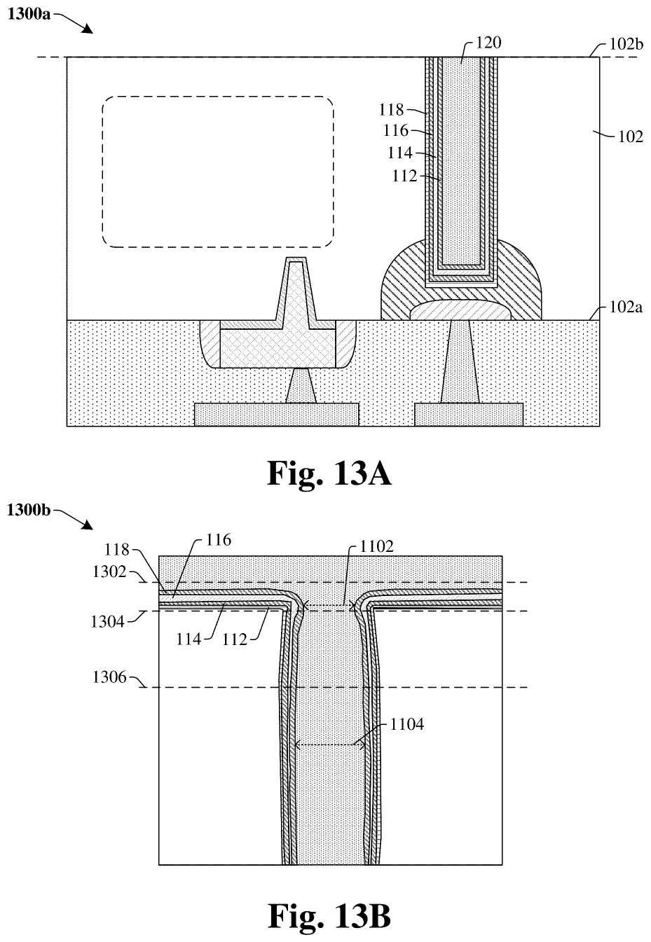

As shown in the cross-sectional view 1300a of FIG. 13A, a planarization process (e.g., a chemical mechanical planarization (CMP) process) is performed on the DTI fill 120, removing a portion of the DTI fill 120 above the second side 102b of the substrate 102. In some embodiments, portions of the first oxide layer 112, the first metal oxide layer 114, second oxide layer 116, and the second metal oxide layer 118 above the second side 102b of the substrate 102 are also removed. In some embodiments, the planarization process removes a portion of the substrate 102, such that the second side 102b of the substrate 102 is closer to the first side 102a of the substrate 102.

As shown in the cross-sectional view 1300b of FIG. 13B, in some embodiments, the planarization process stops at a first line 1302 at or above an upper surface of the second metal oxide layer 118, such that the first oxide layer 112, the first metal oxide layer 114, second oxide layer 116, and the second metal oxide layer 118 remain over the second side of the substrate 102. In other embodiments, the planarization process stops at a second line 1304 at or just below the second side 102b of the substrate 102, such that the first thickness 1102 is still greater than the second thickness 1104. In other embodiments, the planarization process stops at a third line 1306 below the second side 102b of the substrate 102, such that the first thickness 1102 is approximately equal to (e.g., within 10% of) the second thickness 1104.

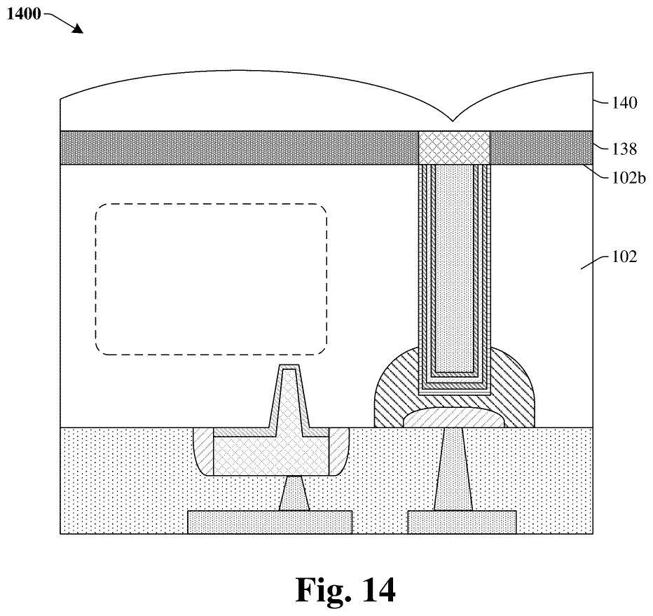

As shown in the cross-sectional view 1400 of FIG. 14, the plurality of color filters 138 and the plurality of microlenses 140 are formed over the second side 102b of the substrate 102. The plurality of color filters 138 are positioned such that individual photodetectors of the plurality of photodetectors (see 205 of FIG. 2B) are covered by an individual color filter of the plurality of color filters 138. That is, only one color filter is directly above any individual photodetector of the plurality of photodetectors (see 205 of FIG. 2B). In some embodiments, the plurality of microlenses 140 are individual to and directly above individual photodetectors. In other embodiments, the plurality of microlenses are offset from being centered on individual photodetectors based on their position in the photodetector array to better direct light towards photodetectors within the photodetector array from an aperture in a structure surrounding the photodetector array.

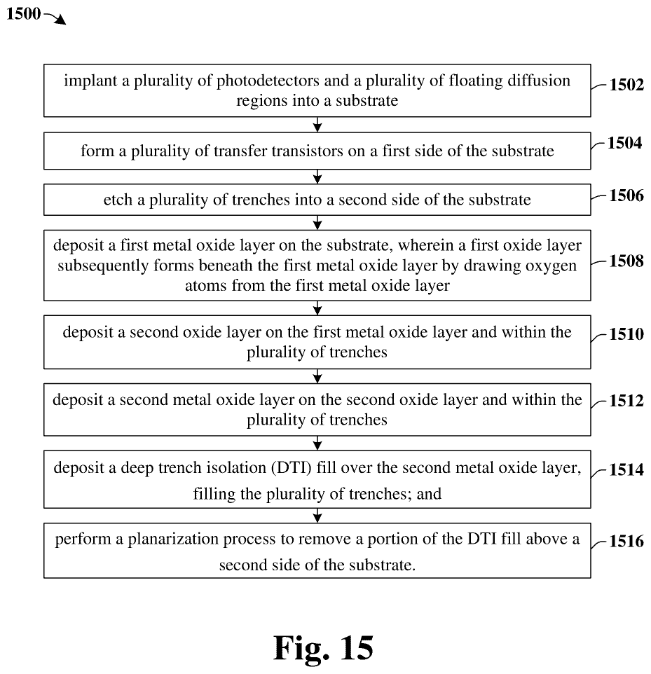

FIG. 15 illustrates a flowchart of some embodiments of a method of forming a DTI structure with complementary dipole generating layers. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1502, a plurality of photodetectors and a plurality of floating diffusion regions are implanted into a substrate. An example of a drawing illustrating this step can be found, for example, in FIG. 5.

At 1504, a plurality of transfer transistors are formed on a first side of the substrate. An example of a drawing illustrating this step can be found, for example, in FIG. 6.

At 1506, a plurality of trenches are etched into a second side of the substrate. An example of a drawing illustrating this step can be found, for example, in FIG. 8.

At 1508, a first metal oxide layer is deposited on the substrate, where a first oxide layer subsequently forms beneath the first metal oxide layer by drawing oxygen atoms from the first metal oxide layer. An example of a drawing illustrating this step can be found, for example, in FIG. 9.

At 1510, a second oxide layer is deposited on the first metal oxide layer and within the plurality of trenches. An example of a drawing illustrating this step can be found, for example, in FIG. 10.

At 1512, a second metal oxide layer is deposited on the second oxide layer and within the plurality of trenches. An example of a drawing illustrating this step can be found, for example, in FIGS. 11A-11D.

At 1514, depositing a deep trench isolation (DTI) fill over the second metal oxide layer, filling the plurality of trenches. An example of a drawing illustrating this step can be found, for example, in FIG. 12.

At 1516, a planarization process is performed to remove a portion of the DTI fill above a second side of the substrate. An example of a drawing illustrating this step can be found, for example, in FIG. 13.

Some embodiments relate to a pixel array, including: a substrate; a plurality of photodetectors within the substrate; a deep trench isolation (DTI) structure with segments extending between photodetectors of the plurality of photodetectors, the DTI structure comprising: a first oxide layer having a first oxygen density; a first metal oxide layer lining inner sidewalls of the first oxide layer and having a second oxygen density greater than the first oxygen density; a second oxide layer lining inner sidewalls of the first metal oxide layer and having a third oxygen density less than the second oxygen density; and a second metal oxide layer lining inner sidewalls of the second oxide layer and having a fourth oxygen density greater than the third oxygen density.

Other embodiments relate to a photodetector array, including: a substrate; a first photodetector within the substrate; a second photodetector within the substrate; a trench defined by inner sidewalls of the substrate, the trench surrounding and extending between the first photodetector and the second photodetector; a first oxide layer lining the inner sidewalls of the trench and a bottom surface of the trench; a first metal oxide layer lining the inner sidewalls of the first oxide layer and an upper surface of the first oxide layer; a second oxide layer lining the inner sidewalls of the first metal oxide layer and an upper surface of the first metal oxide layer; a second metal oxide layer lining the inner sidewalls of the second oxide layer and an upper surface of the second oxide layer; and a fill structure extending between inner sidewalls of the second metal oxide layer.

Yet other embodiments relate to a method of forming an photodetector array, including: implanting a plurality of photodetectors and a plurality of floating diffusion regions into a substrate; forming a plurality of transfer transistors on a first side of the substrate; etching a plurality of trenches into a second side of the substrate; depositing a first metal oxide layer on the substrate, where a first oxide layer subsequently forms beneath the first metal oxide layer by drawing oxygen atoms from the first metal oxide layer; depositing a second oxide layer on the first metal oxide layer and within the plurality of trenches; depositing a second metal oxide layer on the second oxide layer and within the plurality of trenches; depositing a deep trench isolation (DTI) fill over the second metal oxide layer, filling the plurality of trenches; and performing a planarization process to remove a portion of the DTI fill above a second side of the substrate.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel array, comprising:
a substrate;
a plurality of photodetectors within the substrate;
a deep trench isolation (DTI) structure with segments extending between photodetectors of the plurality of photodetectors, the DTI structure comprising:
a first oxide layer having a first oxygen density;
a first metal oxide layer lining inner sidewalls of the first oxide layer and having a second oxygen density greater than the first oxygen density;
a second oxide layer lining inner sidewalls of the first metal oxide layer and having a third oxygen density less than the second oxygen density; and
a second metal oxide layer lining inner sidewalls of the second oxide layer and having a fourth oxygen density greater than the third oxygen density.

2. The pixel array of claim 1, wherein the third oxygen density is within 10% of the value of the first oxygen density, and the second oxygen density is within 10% of the value of the fourth oxygen density.

3. The pixel array of claim 1, wherein the first oxygen density and the third oxygen density are less than 1.25 grams per cubic centimeter, and wherein the second oxygen density and the fourth oxygen density are greater than 1.35 grams per cubic centimeter.

4. The pixel array of claim 1, wherein the first metal oxide layer is over the first oxide layer, and the first oxide layer is over the substrate.

5. The pixel array of claim 4, wherein the second metal oxide layer is over the second oxide layer.

6. The pixel array of claim 1, wherein the first oxide layer has a first thickness and the second oxide layer has a second thickness greater than the first thickness.

7. A photodetector array, comprising:
a substrate;
a first photodetector within the substrate;
a second photodetector within the substrate;
a trench defined by inner sidewalls of the substrate, the trench surrounding and extending between the first photodetector and the second photodetector;
a first oxide layer lining the inner sidewalls of the trench and a bottom surface of the trench;
a first metal oxide layer lining the inner sidewalls of the first oxide layer and an upper surface of the first oxide layer;
a second oxide layer lining the inner sidewalls of the first metal oxide layer and an upper surface of the first metal oxide layer;
a second metal oxide layer lining the inner sidewalls of the second oxide layer and an upper surface of the second oxide layer; and
a fill structure extending between inner sidewalls of the second metal oxide layer.

8. The photodetector array of claim 7, wherein the first oxide layer has a first oxygen density, and the first metal oxide layer has a second oxygen density and extends between inner sidewalls of the first oxide layer, wherein the second oxygen density is greater than the first oxygen density.

9. The photodetector array of claim 7, wherein the second oxide layer has a first oxygen density, and
a second metal oxide layer has a second oxygen density and extending between inner sidewalls of the second oxide layer, wherein the second oxygen density is greater than the first oxygen density.

10. The photodetector array of claim 7, wherein the first oxide layer, the first metal oxide layer, the second oxide layer, and the second metal oxide layer are configured to form a deep trench isolation (DTI) structure, and wherein a flat band voltage between the DTI structure and the substrate is greater than 3.

11. The photodetector array of claim 7, wherein the first oxide layer has a first oxygen density and the first metal oxide layer has a second oxygen density, wherein the first oxygen density and the second oxygen density are configured to generate a first dipole, wherein the second oxide layer has a third oxygen density and the second metal oxide layer has a fourth oxygen density, and wherein the third oxygen density and the fourth oxygen density are configured to generate a second dipole.

12. The photodetector array of claim 7, further comprising a third oxide layer and a third metal oxide layer configured to generate a third dipole, wherein the third oxide layer and a third metal oxide layer extend between and isolate the fill structure from the second metal oxide layer.

13. The photodetector array of claim 12, wherein the first oxide layer, the first metal oxide layer, the second oxide layer, the second metal oxide layer, the third oxide layer, and the third metal oxide layer have a total thickness less than 250 angstroms.

14. A method of forming a photodetector array, comprising:
implanting a plurality of photodetectors and a plurality of floating diffusion regions into a substrate;
forming a plurality of transfer transistors on a first side of the substrate;
etching a plurality of trenches into a second side of the substrate;
depositing a first metal oxide layer on the substrate, wherein a first oxide layer subsequently forms beneath the first metal oxide layer by drawing oxygen atoms from the first metal oxide layer;
depositing a second oxide layer on the first metal oxide layer and within the plurality of trenches;
depositing a second metal oxide layer on the second oxide layer and within the plurality of trenches;
depositing a deep trench isolation (DTI) fill over the second metal oxide layer, filling the plurality of trenches; and
performing a planarization process to remove a portion of the DTI fill above a second side of the substrate.

15. The method of claim 14, wherein the planarization process further removes portions of the first oxide layer, portions of the first metal oxide layer, portions of the second oxide layer, and portions of the second metal oxide layer above the second side of the substrate.

16. The method of claim 14, further comprising:
forming a plurality of color filters over the second side of the substrate; and
forming a plurality of microlenses over the plurality of color filters.

17. The method of claim 14, further comprising:
forming a plurality of positive wells on the first side of the substrate before forming the plurality of floating diffusion regions, wherein the plurality of floating diffusion regions are formed within the plurality of positive wells.

18. The method of claim 14, wherein the DTI fill has a first width between inner sidewalls of the second metal oxide layer and level with the second side of the substrate, and the DTI fill has a second width between inner sidewalls of the second metal oxide layer within the substrate, wherein the first width is less than the second width.

19. The method of claim 18, wherein the planarization process removes a portion of the DTI fill with the first width.

20. The method of claim 14, wherein the first metal oxide layer and the second oxide layer comprise one of aluminum oxide or hafnium oxide, and wherein the first oxide layer and the second oxide layer comprise silicon dioxide.
